(19) United States
(12) Patent Application Publication
(10) Pub. No.: US 2026/0327456 A1
(43) Pub. Date: Oct. 22, 2026

(54) SILICONE RUBBER COMPOSITE FINE PARTICLES, A THERMOSETTING RESIN COMPOSITION CONTAINING THE SAME, A CURED PRODUCT OF THE COMPOSITION, AND ARTICLES

(71) Applicant: Nissin Chemical Industry Co., Ltd., Echizen-shi (JP)

(72) Inventors: Shunsuke CHIBA, Echizen-shi (JP); Junya KANEMOTO, Echizen-shi (JP)

(21) Appl. No.: 19/642,767

(22) Filed: Apr. 9, 2026

(30) Foreign Application Priority Data
Apr. 11, 2025 (JP) 2025-065514

(51) Int. Cl. C09D 183/06; C08G 77/12; C08G 77/18; C08K 3/38; C09D 7/61; H10W 74/47

(52) U.S. Cl. CPC C09D 183/06; C08G 77/12; C08G 77/18; C09D 7/61; H10W 74/473; C08K 2003/385

(57) ABSTRACT

An object of the present invention is to provide silicone rubber fine particles which retain the softness of silicone rubber, do not agglomerate in a thermosetting resin, are well dispersible in the thermosetting resin, and provide a cured product exhibiting a low dielectric constant and a low dielectric loss tangent. An aspect of the present invention provide a silicone rubber composite fine particle having an average particle size of 0.1 to 100 μm, comprising a composite containing (A) a silicone rubber particle and (B) at least one inorganic powder selected from the group consisting of silica, boron nitride, and aluminum nitride, and (C) a condensate of an organoalkoxysilane.

### CROSS REFERENCE

This application claims the benefits of Japanese Patent Application No. 2025-065514 filed on Apr. 11, 2025, the contents of which are hereby incorporated by reference.

An aspect of the present invention relates to a silicone rubber composite fine particle. More particularly, the present invention relates to silicone rubber composite fine particles that have the softness of silicone rubber, do not agglomerate in a thermosetting resin, and impart low dielectric properties and a low dielectric loss tangent to a cured product. The present invention further relates to a thermosetting resin composition containing the composite fine particles, and to a single-layer resin sheet, a laminated resin sheet, a prepreg, a metal-foil-clad laminate, a printed wiring board, an encapsulating material, a fiber-reinforced composite material, and an adhesive.

Conventionally, resin encapsulation has been the mainstream technique in the field of device encapsulation for electronic components such as transistors and ICs, from the viewpoints of productivity and cost. Epoxy resins are mainly used as encapsulation resins because they provide an excellent balance of properties, including electrical properties, moisture resistance, heat resistance, mechanical properties, and adhesion to inserts. However, since epoxy resins are hard and brittle, their use for encapsulation typically requires modification of the epoxy resin itself or the addition of a stress-relieving additive.

Various stress-relieving additives are known, including acrylic rubber, epoxy-modified silicone oil, amino-modified silicone oil, and silicone rubber powder. However, acrylic rubber suffers from poor adhesion because it lacks chemically reactive sites capable of reacting with epoxy resins. Epoxy-modified silicone oil and amino-modified silicone oil tend to provide insufficient stress-relieving effects due to their relatively low molecular weights. In addition, silicone rubber powder exhibits poor compatibility with epoxy resins, resulting in non-uniform dispersion.

For example, Japanese Patent Application Laid-Open No. 2007-23061 discloses an epoxy resin composition in which an epoxy-modified low-molecular-weight silicone is added to an epoxy resin for the purpose of improving fluidity. However, because the epoxy-modified low-molecular-weight silicone has poor compatibility with epoxy resins, it is difficult to uniformly incorporate a sufficient amount thereof to obtain a stress-relieving effect.

Japanese Patent Application Laid-Open No. 2018-172545 discloses a solid encapsulant for compression molding that contains an epoxy resin and an epoxy-modified silicone, and reports excellent stability in warp behavior. However, these approaches alone provide insufficient stress-relieving effects, and further improvement is still required.

Japanese Patent Application Laid-Open No. 2007-146148 discloses reducing the elastic modulus of an epoxy resin by adding a core-shell silicone compound having a silicone oil core encapsulated within a shell formed of an acrylic or other organic polymer. Japanese Patent Application Laid-Open No. H8-85753 discloses improving dispersibility in an epoxy resin by adding silicone fine particles in which spherical silicone rubber fine particles are coated with an organosilsesquioxane resin. However, the acrylic or silicone shell portions do not form chemical bonds with the epoxy resin and therefore exhibit poor adhesion. In addition, since acrylic materials have a glass transition temperature (Tg) that is equal to or lower than the curing temperature of the epoxy resin, melting and agglomeration may occur during curing, which can result in non-uniform dispersion. Accordingly, further improvement remains desirable.

Japanese Patent Application Laid-Open No. 2021-75605 discloses epoxy-modified silicone fine particles that have the softness of silicone rubber, do not agglomerate in a thermosetting resin, and exhibit excellent adhesion to the thermosetting resin. However, additives providing further improved stress-relief performance are still desired.
Patent Literature 1: Japanese Patent Application Laid-Open No. 2007-23061
Patent Literature 2: Japanese Patent Application Laid-Open No. 2018-172545
Patent Literature 3: Japanese Patent Application Laid-Open No. 2007-146148
Patent Literature 4: Japanese Patent Application Laid-Open No. Hei 8-85753
Patent Literature 5: Japanese Patent Application Laid-Open No. 2021-75605

The present invention has been made in view of the above circumstances and relates to silicone rubber fine particles.

In particular, an object of the present invention is to provide silicone rubber fine particles which retain the softness of silicone rubber, do not agglomerate in a thermosetting resin, are well dispersible in the thermosetting resin, and provide a cured product exhibiting a low dielectric constant and a low dielectric loss tangent.

As a result of intensive studies conducted to achieve the above object, the present inventors have found that silicone rubber composite fine particles containing at least one inorganic powder selected from the group consisting of silica, boron nitride, and aluminum nitride retain the characteristics of silicone rubber, do not agglomerate in a thermosetting resin, exhibit good dispersibility therein, and provide a cured product having a low dielectric constant and a low dielectric loss tangent, thereby completing the present invention.

That is, an aspect of the present invention provides:
[1]A silicone rubber composite fine particle having an average particle size of 0.1 to 100 μm, comprising
   a composite containing (A) a silicone rubber particle and (B) at least one inorganic powder selected from the group consisting of silica, boron nitride, and aluminum nitride, and
   (C) a condensate of an organoalkoxysilane.

Other aspects of the present invention provide silicone rubber composite fine particles or methods for preparing the silicone rubber composite fine particles having the following configurations.
[2] The silicone rubber composite fine particle according to the item [1], comprising
   0.1 to 80% by mass of (A) the silicone rubber particle,
   0.1 to 80% by mass of (B) at least one inorganic powder selected from the group consisting of silica, boron nitride, and aluminum nitride, and
   0.1 to 80% by mass of (C) the condensate of the organoalkoxysilane,
   each based on 100% by mass of the silicone rubber composite fine particle.
[3] The silicone rubber composite fine particle according to the item [1] or [2],
   wherein the silicone rubber of component (A) has a structure represented by the following formula (1):

—(R¹₂SiO)ₐ— (1)
wherein, in formula (1), R¹ is, independently of each other, a substituted or unsubstituted monovalent hydrocarbon group having 1 to 20 carbon atoms, and a is an integer of 5 to 5,000.
[4] The silicone rubber composite fine particle according to any one of the items [1] to [3], wherein the organoalkoxysilane (C) is at least one selected from the group consisting of a trialkoxysilane represented by the following general formula (2) and a tetraalkoxysilane represented by the following general formula (3):

R²Si(OR³)₃ (2)

Si(OR³)₄ (3)
wherein, in formula (2), R² is a monovalent hydrocarbon group having 1 to 20 carbon atoms, and, in formulas (2) and (3), R³ is, independently of each other, an alkyl group having 1 to 6 carbon atoms.
[5] The silicone rubber composite fine particle according to any one of the items [1] to [4],
   wherein the silicone rubber composite fine particle consists of the composite of (A) the silicone rubber particle and (B) at least one inorganic powder selected from the group consisting of silica, boron nitride, and aluminum nitride, and (C) the condensate of the organoalkoxysilane.
[6]A thermosetting resin composition comprising a thermosetting resin and the silicone rubber composite fine particle according to any one of the items [1] to [5],
   wherein an amount of the silicone rubber composite fine particle is 0.5 to 80 parts by mass, relative to 100 parts by mass of the thermosetting resin.
[7]A cured product of the thermosetting resin composition according to the item [6].
[8]A semiconductor element encapsulated with the cured product according to the item [7].
[9]A method for preparing a silicone rubber composite fine particle, comprising steps of
   mixing (A′) a curable organopolysiloxane composition; (B) at least one inorganic powder selected from the group consisting of silica, boron nitride, and aluminum nitride; water; and optionally a surfactant, and curing the curable organopolysiloxane composition to obtain an aqueous dispersion of a composite, and
   subjecting (C) an organoalkoxysilane to a hydrolysis and condensation reaction in the aqueous dispersion of the composite obtained in the said step, to obtain the silicone rubber composite fine particle having an average particle size of 0.1 to 100 μm.
[10] The method for preparing the silicone rubber composite fine particle according to the item [9], wherein an amount of component (B) is 0.1 to 80 parts by mass and an amount of the organoalkoxysilane (C) is 0.1 to 80 parts by mass, relative to total 100 parts by mass of the organopolysiloxane in component (A′), the inorganic powder (B), and the organoalkoxysilane (C).
[11] The method for preparing the silicone rubber composite fine particle according to the item [9] or [10], wherein the curable organopolysiloxane composition (A′) is a condensation-curable organopolysiloxane composition, a radical-curable organopolysiloxane composition, or an addition-curable organopolysiloxane composition.
[12] The method for preparing the silicone rubber composite fine particle according to any one of the items [9] to [11], wherein the organoalkoxysilane (C) is at least one selected from the group consisting of a trialkoxysilane represented by the following general formula (2) and a tetraalkoxysilane represented by the following general formula (3):

R²Si(OR³)₃ (2)

Si(OR³)₄ (3)
wherein, in formula (2), R² is a monovalent hydrocarbon group having 1 to 20 carbon atoms, and in formulas (2) and (3), R³ is, independently of each other, an alkyl group having 1 to 6 carbon atoms.

The composite fine particles of the present invention have a softness of silicone rubber, and impart to a cured product a low dielectric loss tangent inherently possessed by at least one inorganic powder selected from the group consisting of silica, boron nitride, and aluminum nitride. Incorporation of the composite fine particles containing the inorganic powder into a thermosetting resin, particularly an epoxy resin, enables the cured product to exhibit superior mechanical properties, such as flexural modulus, as compared with a cured product obtained by blending the inorganic powder alone into the thermosetting resin. The thermosetting resin composition of the present invention is suitable for use as a single-layer resin sheet, a laminated resin sheet, a prepreg, a metal-foil-clad laminate, a printed wiring board, an encapsulating material, a fiber-reinforced composite material, and an adhesive.

### DETAILED DESCRIPTION

Embodiments of the present invention will now be described in more detail.

A silicone rubber composite fine particle of the present invention comprises a composite containing (A) a silicone rubber particle and (B) at least one inorganic powder selected from the group consisting of silica, boron nitride, and aluminum nitride, the composite being coated with (C) a condensate of an organoalkoxysilane, and has an average particle size of 0.1 to 100 μm.

The composite containing the silicone rubber particles (A) and at least one inorganic powder (B) selected from the group consisting of silica, boron nitride, and aluminum nitride is a composite fine particle obtained by adding the inorganic powder during preparation of the silicone rubber particle.

The silicone rubber of the silicone rubber particle (A) preferably has, in the molecular structure, a linear organopolysiloxane block represented by the following general formula (1), and is a spherical silicone cured product exhibiting rubber elasticity.

—(R¹₂SiO)ₐ (1)

In formula (1), R¹ is a substituted or unsubstituted monovalent hydrocarbon group having 1 to 20 carbon atoms, or a group selected from reactive group-containing organic groups such as an epoxy group, an amino group, a mercapto group, an acryloxy group, and a methacryloxy group. Examples of the monovalent hydrocarbon group having 1 to 20 carbon atoms include alkyl groups such as a methyl group, an ethyl group, a propyl group, and a butyl group; aryl groups such as a phenyl group and a tolyl group; alkenyl groups such as a vinyl group and an allyl group; and aralkyl groups such as a β-phenylethyl group and a β-phenylpropyl group. The number of carbon atoms is preferably 1 to 10, more preferably 1 to 6. Examples of the substituted groups include groups in which some or all hydrogen atoms bonded to carbon atoms of the hydrocarbon group are substituted with halogen atoms or the like, for example, monovalent halogenated hydrocarbon groups such as a chloromethyl group and a 3,3,3-trifluoropropyl group. Preferably, 90 mol % or more of R¹ is a methyl group.

In formula (1), “a” is an integer from 5 to 5,000, preferably from 10 to 1,000. If “a” is less than 5, the characteristic properties of the linear organopolysiloxane are not sufficiently exhibited, resulting in insufficient internal stress relaxation. Although no particular upper limit is imposed on “a”, in practice, preparation of silicone rubber particles becomes difficult when “a” exceeds 5,000.

The silicone rubber particle (A) may contain, within the particle, silicone oil, an organosilane, an inorganic powder other than component (B), an organic powder, and the like. The silicone rubber particle preferably has an average particle size from 0.1 to 100 m, more preferably from 1 to 30 m. If the average particle size of the silicone rubber particles is less than the above lower limit, particle fluidity may decrease and cohesiveness may increase. If the average particle size exceeds the above upper limit, the properties of the substrate may be adversely affected. In the present invention, the term “average particle size” means a volume-based average particle size measured using a laser diffraction particle size distribution analyzer.

Examples of reactions for preparing the silicone rubber particles include a condensation reaction between a methoxysilyl group (≡SiOCH₃) and a hydroxysilyl group (≡SiOH), a radical reaction between a mercaptosilyl group (≡SiSH) and a vinylsilyl group (≡SiCH═CH₂), and an addition reaction between a vinylsilyl group (≡SiCH═CH₂) and a ≡SiH group. From the standpoint of reactivity and process control, an addition reaction is preferred.

The silicone rubber composite fine particle of the present invention can be obtained by a preparation method comprising a step of mixing the curable organopolysiloxane composition (A′); at least one inorganic powder (B) selected from the group consisting of silica, boron nitride, and aluminum nitride; water; and optionally a surfactant, and curing the addition-curable organopolysiloxane composition to obtain an aqueous dispersion of the composite fine particle; and a step of subjecting the organoalkoxysilane (C) to a hydrolytic condensation reaction in the aqueous dispersion of the composite to obtain a silicone rubber composite fine particle having an average particle size of 0.1 to 100 μm. As mentioned above, examples of the curable organopolysiloxane composition (A′) a condensation-curable organopolysiloxane composition, a radical-curable organopolysiloxane composition, or an addition-curable organopolysiloxane composition. Preferred is, for example, that (a1) a vinyl group-containing organopolysiloxane and (a2) an organohydrogen polysiloxane are addition reacted in the presence of (a3) a platinum-based catalyst and cured to thereby obtain an addition-curable organopolysiloxane composition. The amount of component (B) is 0.1 to 80 parts by mass, preferably 0.1 to 50 parts by mass, more preferably 1 to 30 parts by mass, and the amount of the organoalkoxysilane (C) is 0.1 to 80 parts by mass, preferably 10 to 80 parts by mass, relative to total 100 parts by mass of components (A′), (B), and (C).

The silicone rubber composite fine particles of the present invention have an average particle size of 0.1 to 100 μm, preferably 1 to 30 μm, more preferably 1 to 20 μm. If the average particle size of the silicone rubber composite fine particles is less than the above lower limit, the fluidity of the particles may decrease and cohesiveness may increase. If the average particle size exceeds the above upper limit, the properties of the substrate may be impaired. In the present invention, the average particle size refers to a volume-based average particle size measured using a laser diffraction particle size distribution analyzer.

In the addition reaction-cured organopolysiloxane composition, component (a1) is the main component of organopolysiloxane to prepare the silicone rubber particle. Component (a1) is addition reacted with component (a2) with the catalyst effect of component (a3) to be cured. Component (a1) is required to have at least two vinyl groups bonded to silicon atoms per molecule. The vinyl groups may be located at any position within the molecule, but are preferably present at least at the molecular chain ends. Examples of organic groups bonded to the silicon atoms other than vinyl groups include groups similar to R¹ as described above, and preferably 90 mol % or more of all the organic groups are methyl groups. The molecular structure of the vinyl group-containing organopolysiloxane (a1) may be linear, branched, or a mixture thereof. The molecular weight thereof is not particularly limited; however, in order for the cured product to form a rubber-like elastomer, the viscosity at 25 °C is preferably 1 cP or more.

Examples of component (a1) include a linear, cyclic, or branched organopolysiloxane represented by the following formula.

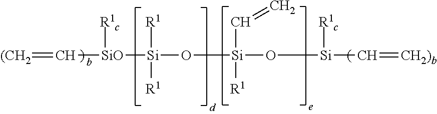

In the above formula, b and c are integers from 0 to 3 satisfying the equation of b+c=3, d is a positive number, e is 0 or a positive number, and 2b+e≥2.

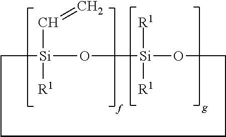

In the above formula, f is a positive number of 2 or greater, g is 0 or a positive integer, and f+g is from 4 to 8.

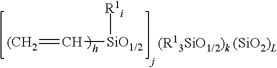

In the above formula, h is 1, 2, or 3, i is 0, 1, or 2, h+i=3, and j, k, and L are positive numbers.

Component (a2) is a crosslinking agent for component (a1). Curing proceeds by an addition reaction between hydrogen atoms bonded to silicon atoms (hereinafter also referred to as Si—H groups or hydrosilyl groups) in component (a2) and vinyl groups present in component (a1), in the presence of catalyst (a3). Accordingly, component (a2) is required to have at least two hydrogen atoms bonded to silicon atoms per molecule. Organic groups other than hydrogen atoms that are bonded to the silicon atoms may be selected from the monovalent organic groups exemplified above as R¹. Preferably, 90 mol % or more of the total number of moles of the organic groups bonded to the silicon atoms are methyl groups. The molecular structure of component (a2) is not particularly limited, and may be linear, branched, cyclic, or a mixture thereof. The molecular weight of component (a2) is not particularly limited; however, from the viewpoint of good compatibility with component (a1), the viscosity at 25 °C is preferably from 1 to 10,000 cP.

The amount of component (a2) is preferably such that the ratio of the number of hydrosilyl groups in component (a2) to the number of vinyl groups in component (a1) is from 0.5 to 20, preferably from 0.5 to 5. If the amount of component (a2) is less than the lower limit, sufficient curability may not be obtained. If the amount of component (a2) exceeds the upper limit, the physical properties of the cured rubber may deteriorate.

Examples of component (a2) include a linear, cyclic, or branched polyorganohydrogen siloxane represented by the following formula.

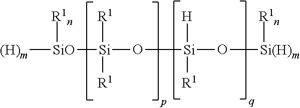

In the formula, m is 0 or 1, n is 2 or 3, m+n=3, p is 0 or a positive number, q is 0 or a positive number; and 2m+q≥2.

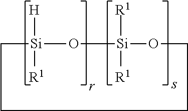

In the formula, r is a positive number of 2 or greater; s is 0 or a positive number, and r+s is from 4 to 8.

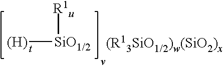

In the formula, t is 1, 2, or 3, u is 0, 1, or 2, (t+u)=3, and v, w, and x are positive numbers.

Component (a3) is a catalyst for the addition reaction between silicon-bonded vinyl groups in component (a1) and hydrosilyl groups in component (a2), and may be appropriately selected from conventionally known addition reaction catalysts. Examples of component (a3) include, for example, platinum-based catalysts such as platinum supported on carbon or silica, chloroplatinic acid, platinum-olefin complexes, platinum-alcohol complexes, platinum-phosphorus complexes, platinum-vinyl-containing siloxane complexes, and platinum coordination compounds.

The amount of component (a3) may be any catalytic amount sufficient to allow the addition reaction to proceed; however, the amount of platinum atom is preferably in the range of 1 to 100 ppm, based on the total weight of component (a1). When the amount of platinum is less than 1 ppm, curing tends to slow and the reaction is more easily affected by catalyst poisoning. On the other hand, when the amount of platinum exceeds 100 ppm, no significant increase in curing rate is achieved, and such an amount is economically disadvantageous.

Examples of a method for curing the silicone in an emulsion include mixing predetermined amounts of the vinyl group-containing organopolysiloxane (a1) and the organohydrogen polysiloxane (a2) to prepare an organopolysiloxane composition, followed by adding water and a surfactant to the resulting composition, and emulsifying the mixture using a commercially available high-shear mixer or the like.

In the step of curing the silicone in an emulsion, it is preferred to add at least one inorganic powder (B) selected from the group consisting of silica, boron nitride, and aluminum nitride to a mixture of the vinyl group-containing organopolysiloxane (a1) and the organohydrogen polysiloxane (a2), followed by mixing and emulsifying to thereby obtain the composite (fine particles).

The inorganic powder (B) is at least one selected from the group consisting of silica, boron nitride, and aluminum nitride, and may be a commercially available product. Examples of silica include true spherical particles having a particle size from 0.1 to 100 m, such as “Sylobloc,” “Syloid,” and “Sylojet” manufactured by W. R. Grace & Co.; “Sylysia” (silica powder) manufactured by Fuji Silysia Chemical Ltd.; “Carplex” manufactured by DSL Japan Co., Ltd.; and “Sunsphere” manufactured by AGC Si-Tech Co., Ltd. Examples of boron nitride include scale-like to true spherical particles having a particle size from 0.1 to 100 m, and commercially available products such as SP-2 and SP-3 manufactured by Denka Company Limited. Examples of aluminum nitride include scale-like to true spherical particles having a particle size from 0.1 to 100 m, and commercially available products such as HF-01D, HF-05, and HF-20 manufactured by Tokuyama Corporation.

The content of the inorganic powder (B) in the silicone rubber composite fine particles is preferably from 0.1 to 80% by mass, more preferably from 0.1 to 50% by mass, and even more preferably from 1 to 30% by mass, based on 100% by mass of the silicone rubber composite fine particles. The content of the silicone rubber particle (A) in the silicone rubber composite fine particles, excluding the amount of component (B), is from 0.1 to 80% by mass, preferably from 10 to 80% by mass, and more preferably from 40 to 70% by mass, based on 100% by mass of the silicone rubber composite fine particles.

The surfactant is preferably nonionic surfactants such as a polyoxyethylene alkyl phenyl ether, a polyoxyethylene alkyl ether, a polyoxyethylene sorbitan fatty acid ester, and a glycerin fatty acid ester, but may be an anionic surfactant. The added amount of the surfactant is preferably in the range of 0.01 to 20 parts by mass, more preferably 0.05 to 10 parts by mass, relative to 100 parts by mass of the emulsion. If the amount of the surfactant is less than the lower limit, fine composite particles may not be obtained. If the amount exceeds the upper limit, it may be difficult for the organoalkoxysilane condensate (C) to be present on the surface (outermost surface) of the composite fine particles containing the silicone rubber particles and the inorganic powder, or at the interface between the silicone rubber particles and the inorganic powder in the aqueous dispersion of the composite. The aforementioned term “100 parts by mass of the emulsion” may be the total 100 parts by mass of the organopolysiloxane composition, the inorganic powder, the water, and the surfactant.

The platinum-based catalyst (a3) is added to the emulsion to cure organopolysiloxanes (a1) and (a2), thereby forming a dispersion of cured silicone rubber. A known reaction control agent may be added as the platinum-based catalyst. When the platinum-based catalyst and the reaction control agent do not readily disperse in water, a surfactant may be used to facilitate dispersion in water prior to their addition. In this manner, an aqueous dispersion of composite fine particles obtained from the silicone rubber particles (A) and the inorganic powder (B) is prepared.

A surfactant may be added to the aqueous dispersion. Addition of the surfactant improves the dispersibility of the composite fine particles contained in the aqueous dispersion. In addition, the organoalkoxysilane condensate (C), described below, can uniformly cover the surface of the composite fine particles. The type of surfactant is not particularly limited, and any conventionally known surfactant may be appropriately selected. Examples of the surfactant include cationic surfactants such as quaternary ammonium salts and alkylamine salts; zwitterionic surfactants such as alkylbetaines; nonionic surfactants such as polyoxyethylene alkyl ethers, polyoxyethylene alkyl phenyl ethers, sorbitan fatty acid esters, and glycerin fatty acid esters; and anionic surfactants such as organic sulfonates and alkyl sulfate esters. These surfactants may be used alone or in combination of two or more thereof.

The organoalkoxysilane condensate in the silicone rubber composite fine particles of the present invention may be present at either or both of the surface (outermost surface) of the composite fine particles containing the silicone rubber particles and the inorganic powder, and at the interface between the silicone rubber particles and the inorganic powder. The organoalkoxysilane (C), and if necessary, an alkaline substance or an alkaline aqueous solution, are added to the aqueous dispersion of the composite fine particle and mixed. Then, a hydrolysis and condensation reaction of the organoalkoxysilane is proceeded, an organoalkoxysilane condensate is formed on the surface (outermost surface) of the composite fine particles or the interface between the silicone rubber particles and the inorganic powder, to thereby obtain the silicone rubber composite fine particles of the present invention. Preferably, the silicone rubber composite fine particles include a form in which the organoalkoxysilane condensate covers a portion of the outermost surface of the composite fine particle, and a form in which the organoalkoxysilane condensate covers the entire outermost surface of the composite fine particle. More preferably, the silicone rubber composite fine particles include a form in which the organoalkoxysilane condensate covers 20% to 100% of the surface of the composite fine particle. In such forms, the organoalkoxysilane condensate may also be present at the interface between the silicone rubber particle and the inorganic powder.

More preferably, the silicone rubber composite fine particles of the present invention contains only the composite fine particle of the silicone rubber particle and the inorganic powder, and the organoalkoxysilane condensate (C).

The step of obtaining the silicone rubber composite fine particles containing the composite fine particle and the organoalkoxysilane condensate (C) may be carried out in the presence of an alkaline substance or an alkaline aqueous solution. Any alkaline substance or alkaline aqueous solution having a catalyst effect in the hydrolytic condensation reaction of the organoalkoxysilane (C) may be used. Examples of the alkaline substance or alkaline aqueous solution include alkali metal hydroxides such as potassium hydroxide, sodium hydroxide, and lithium hydroxide; alkaline earth metal hydroxides such as calcium hydroxide and barium hydroxide; alkali metal carbonates such as potassium carbonate and sodium carbonate; amines such as ammonia, monomethylamine, dimethylamine, monoethylamine, diethylamine, or ethylenediamine; and quaternary ammonium hydroxides such as tetramethylammonium hydroxide. Among these, ammonia is most suitable because of its high solubility in water, excellent catalytic activity, and ease of removal from the powder by volatilization. A commercially available aqueous ammonia solution having a concentration of 25% by mass may be used. The amount of the aqueous ammonia solution to be added is such that the amount of the 25% by mass aqueous ammonia is 80 to 1,000 parts by mass, preferably 200 to 800 parts by mass, relative to 100 parts by mass in total of the silane compound or the organopolysiloxane (for example, component (a1) and component (a2)), which are raw materials of the silicone rubber particle. If the amount of ammonia is insufficient, the organoalkoxysilane condensate may fail to adhere to the silicone rubber composite fine particles, which may result in the formation of homoparticles of the silane.

The organoalkoxysilane (C) may be, for example, a trialkoxysilane represented by the following general formula (2) or a tetraalkoxysilane represented by the following general formula (3).

R²Si(OR³)₃ (2)

Si(OR³)₄ (3)

In formulas (2) and (3), R² is a monovalent hydrocarbon group having 1 to 20 carbon atoms, and the monovalent hydrocarbon groups exemplified above for R¹ may also be employed as R². R² is preferably an alkyl group having 1 to 10 carbon atoms, more preferably 1 to 5 carbon atoms. R³ is, independently of each other, an alkyl group having 1 to 6 carbon atoms, such as methyl, ethyl, propyl, and butyl groups.

Examples of the organotrialkoxysilane represented by formula (2) include methyltrimethoxysilane, methyltriethoxysilane, methyltripropoxysilane, methyltributoxysilane, ethyltrimethoxysilane, propyltrimethoxysilane, and butyltrimethoxysilane. Examples of the organotetraalkoxysilane represented by formula (3) include tetramethoxysilane and tetraethoxysilane. Among them, methyltrimethoxysilane is preferred.

The amount of the organoalkoxysilane condensate (C) in the silicone rubber composite fine particles is such that the amount of the organoalkoxysilane condensate (C) is 0.1 to 80% by mass, preferably 10 to 80% by mass, more preferably 10 to 40% by mass, based on 100% by mass of the silicone rubber composite fine particles.

In the preparation of the silicone rubber composite fine particles of the present invention, the amount of the organoalkoxysilane (C) is preferably 0.1 to 100 parts by mass, more preferably 5 to 30 parts by mass, relative to 100 parts by mass of water in the aqueous dispersion of the composite fine particles. If the amount of the organoalkoxysilane (C) is excessively large, undesired lump formation may occur. Further, excessively vigorous stirring during the hydrolytic condensation tends to cause particle agglomeration or fusion, particularly when the amount of the organoalkoxysilane is large. Accordingly, stirring is preferably carried out under as mild conditions as possible. Examples of suitable stirring devices include propeller blades, flat blades, and anchor impellers. The reaction temperature during the hydrolytic condensation is preferably 0 to 60 °C, particularly preferably 5 to 20 °C. When the reaction temperature is below 0 °C, the liquid may solidify. On the other hand, when the reaction temperature exceeds 60 °C, particles consisting solely of the generated hydrolytic condensate may form, which may result in agglomeration or fusion between particles.

During the hydrolysis and condensation reaction of the organoalkoxysilane, the alkaline substance or alkaline aqueous solution may be added simultaneously with the organoalkoxysilane, or may be added after the organoalkoxysilane has been added. When a relatively large amount of the organoalkoxysilane is used, it is preferable to add the alkaline substance or alkaline aqueous solution in advance to the aqueous dispersion of the composite fine particles. The organoalkoxysilane may be added to the reaction system in a single portion; however, when used in a large amount, gradual addition in small portions over time is preferable, because one-time addition may cause agglomeration or fusion between particles.

Stirring during the hydrolysis and condensation reactions is preferably continued for a period of time after completion of the addition of the organoalkoxysilane until the reactions are completed. Heating may be performed to complete the hydrolysis and condensation reactions, and if necessary, an acidic substance may be added for neutralization. As a result, the surface of the silicone rubber composite fine particles is coated with the hydrolytic condensate of the organoalkoxysilane. After completion of the reaction, the dispersion may be concentrated by, for example, heat dehydration, filtration, centrifugation, decantation, or the like. If necessary, the concentrated dispersion may be washed, followed by removal of moisture by methods such as heated drying at atmospheric pressure or under reduced pressure, spray drying by spraying the dispersion into an air stream, or heated drying using a fluidized heating medium. If the silicone composite fine particles thus obtained exhibit slight agglomeration, the particles may be appropriately deagglomerated using a pulverizer such as a jet mill, a ball mill, or a hammer mill.

### Thermosetting Resin Composition

The present invention further provides a thermosetting resin composition containing a thermosetting resin and the silicone rubber composite fine particles. The amount of the silicone rubber composite fine particles is 0.5 to 80 parts by mass, preferably 2 to 50 parts by mass, relative to 100 parts by mass of the thermosetting resin.

The thermosetting resin is a compound having reactive functional groups capable of forming a crosslinked structure to cure a resin layer. Examples of such thermosetting resins include acrylate compounds, epoxy compounds, bismaleimide compounds, cyanate compounds, and phenol compounds. Among these, from the viewpoints of the viscosity of the resin layer and the coefficient of thermal expansion of the cured product, at least one compound selected from the group consisting of acrylate compounds, epoxy compounds, bismaleimide compounds, and phenol compounds is preferred; at least one selected from the group consisting of acrylate compounds, epoxy compounds, and bismaleimide compounds is more preferred; and from the viewpoint of curing rate, at least one selected from the group consisting of acrylate compounds and epoxy compounds is still more preferred. These thermosetting resins may be used alone or in combination with two or more thereof. An epoxy resin is particularly preferred.

The epoxy resin is not particularly limited, and may be any epoxy resin commonly used in a thermosetting resin composition, and particularly in an encapsulation epoxy resin composition. Examples of the epoxy resin include epoxidized novolac resins (novolac-type epoxy resins) such as phenol novolac-type epoxy resins, orthocresol novolac-type epoxy resins, and epoxy resins having a triphenylmethane skeleton, which are obtained by epoxidizing a novolac resin produced by subjecting phenols such as phenol, cresol, xylenol, resorcinol, catechol, bisphenol A, and bisphenol F and/or naphthols such as α-naphthol, β-naphthol, and dihydroxynaphthalene, to condensation or co-condensation, in the presence of an acidic catalyst, with compounds having aldehyde groups such as formaldehyde, acetaldehyde, propionaldehyde, benzaldehyde, and salicylaldehyde; diglycidyl ethers (bisphenol-type epoxy resins) such as bisphenol A, bisphenol F, and bisphenol S; diglycidyl ethers (biphenyl-type epoxy resins) such as alkyl-substituted or unsubstituted biphenol; stilbene-type epoxy resins; hydroquinone-type epoxy resins; glycidyl ester-type epoxy resins obtained by reacting polyacids such as phthalic acid and dimer acid with epichlorohydrin; glycidylamine-type epoxy resins obtained by reacting polyamines such as diaminodiphenylmethane and isocyanuric acid with epichlorohydrin; epoxidized products of co-condensation resins of dicyclopentadiene and phenols (dicyclopentadiene-type epoxy resins); epoxy resins having a naphthalene ring (naphthalene-type epoxy resins); aralkyl-type phenolic resins synthesized from phenols and/or naphthols with dimethoxy para-xylene or bis(methoxymethyl)biphenyl; epoxidized products of aralkyl-type phenolic resins such as a naphthol-aralkyl resin; trimethylolpropane-type epoxy resins; terpene-modified epoxy resins; linear aliphatic epoxy resins obtained by oxidizing olefinic bonds with peracids such as peracetic acid; alicyclic epoxy resins; and sulfur atom-containing epoxy resins. These epoxy resins may be used alone or in combination with two or more thereof.

The thermosetting resin content in the thermosetting resin composition is not particularly limited, and in view of sufficient curability, is, for example, preferably 30% by mass or more, more preferably 40% by mass or more, based on the mass of the solid component of the thermosetting resin composition. The content of the thermosetting resin is preferably, for example, 99% by mass or less, more preferably 95% by mass or less, even more preferably 70% by mass or less, based on the mass of the solid component of the resin layer or thermosetting resin composition, in view of fluidity of the resin layer.

The thermosetting resin composition preferably contains a curing agent. The curing agent is not particularly limited and may be any curing agent commonly used in thermosetting resin compositions, and particularly encapsulation epoxy resin compositions. Examples of the curing agent include novolac-type phenolic resins obtained by subjecting phenols such as phenol, cresol, resorcinol, catechol, bisphenol A, bisphenol F, phenylphenol, and aminophenol and/or naphthols such as α-naphthol, β-naphthol, and dihydroxynaphthalene, to condensation or co-condensation, in the presence of an acidic catalyst, with compounds having aldehyde groups such as formaldehyde, benzaldehyde, and salicylaldehyde; phenol-aralkyl resins synthesized from phenols and/or naphthols with dimethoxy para-xylene or bis(methoxymethyl)biphenyl; aralkyl-type phenolic resins such as naphthol-aralkyl resins; copolymerized phenol-aralkyl resins in which a phenol-novolac structure and a phenol-aralkyl structure are repeated randomly, in blocks, or alternately; para-xylylene and/or meta-xylylene-modified phenolic resins; melamine-modified phenolic resins; terpene-modified phenolic resins; dicyclopentadiene-type phenolic resins; cyclopentadiene-type phenolic resins; and polycyclic aromatic ring-modified phenolic resins. These curing agents may be used alone or in combination with two or more thereof.

The thermosetting resin composition of the present invention may further contain a curing accelerator for promoting the curing reaction between the thermosetting resin and the curing agent, as well as various inorganic fillers such as fused silica, crystalline silica, alumina, magnesia, magnesium silicate, and aluminum. Further, other conventionally known additives may be appropriately incorporated into the thermosetting resin composition, provided that the effects of the present invention are not impaired.

The thermosetting resin composition of the present invention may be prepared by any conventionally known method. For example, the above-described components may be mixed according to conventional techniques. The thermosetting resin composition containing the silicone composite fine particles of the present invention, particularly an epoxy resin composition, exhibits excellent stress-relief performance and is therefore suitable as an encapsulant. Accordingly, the thermosetting resin composition of the present invention is used as a constituent material for a prepreg, a single-layer resin sheet, a laminated resin sheet, a metal-foil-clad laminate, a printed wiring board, and a semiconductor package. For example, a prepreg can be obtained by impregnating or coating a base material with a solution prepared by dissolving the composition of the present embodiment in a solvent, followed by drying. Further, by using a releasable plastic film as a support and applying thereto a solution prepared by dissolving the composition of the present embodiment in a solvent, followed by drying, a build-up film or a dry film solder resist can be obtained. Further, the thermosetting resin composition of the present invention is useful as an encapsulant for semiconductor elements and the like, and can be suitably applied to an object, such as an electronic circuit board, by a known coating method.

### EXAMPLES

The present invention will be explained in more detail with reference to the following Examples and Comparative Examples; however, the present invention is not limited to the following Examples. In the following examples, “parts” and “%” respectively refer to “parts by mass” and “% by mass”.

### Preparation of Composite Containing Silicone Rubber Particle and Inorganic Powder

### Preparation Example 1

In a 0.5-L glass beaker, were placed 56 g of a methylvinylsiloxane represented by formula (1) (kinematic viscosity: 8.5 mm²/s; vinyl value: 0.21 mol/100 g) and 16 g of a polymethylhydrosiloxane represented by formula (2) (kinematic viscosity: 121 mm²/s; H value: 0.85 mol/100 g), and the mixture was stirred at 2,000 rpm using a homogenizing mixer. Subsequently, 0.22 g of polyoxyethylene (9 mol added) lauryl ether, 38 g of water, and 16 g of boron nitride (SP-3, manufactured by Denka Co., Ltd.) were added to the reaction mixture, and stirring was continued at 8,000 rpm. Upon continued stirring, phase inversion occurred and thickening was observed. Thereafter, 240 g of dilution water was added to dilute the reaction mixture, thereby obtaining an O/W-type silicone oil emulsion.

The silicone oil emulsion was then transferred to a glass flask equipped with a stirring device having an anchor impeller, followed by adding a mixture of 0.84 g of a toluene solution of a chloroplatinic acid-olefin complex (platinum content of 0.5%) and 1.92 g of polyoxyethylene (9 mol added) lauryl ether with stirring at room temperature. After reacting for 12 hours, an aqueous dispersion liquid of the composite fine particle was obtained. The solid component was about 21%.

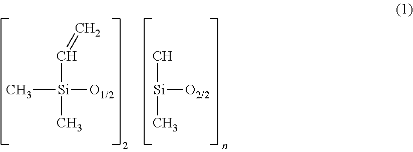

n is 10.5

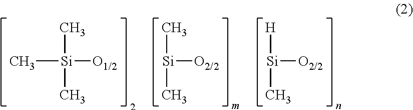

m is 48 and n is 50

### Preparation Example 2

In a 0.5-L glass beaker, were placed 56 g of a methylvinylsiloxane represented by formula (1) (kinematic viscosity of 8.5 mm²/s, vinyl value of 0.21 (mol/100 g)) and 16 g of a polymethylhydrosiloxane represented by formula (2) (kinematic viscosity of 121 mm²/s, H value of 0.85 mol/100 g), and the mixture was stirred at 2,000 rpm using a homogenizing mixer. Subsequently, 38 g of water and 4 g of boron nitride (SP-3, manufactured by Denka Company Limited) were added to the reaction mixture, and stirring was continued at 8,000 rpm. Upon continued stirring, phase inversion occurred and thickening was observed. Thereafter, 240 g of dilution water was added to dilute the reaction mixture, thereby obtaining an O/W-type silicone oil emulsion.

The silicone oil emulsion was then transferred to a glass flask equipped with a stirring device having an anchor impeller, followed by adding 0.84 g of a toluene solution of a chloroplatinic acid-olefin complex (platinum content of 0.5%) with stirring at room temperature. After reacting for 12 hours, an aqueous dispersion liquid of the composite fine particle was obtained. The solid component was about 21%.

### Preparation Example 3

In a 0.5-L glass beaker, were placed 56 g of a methylvinylsiloxane represented by formula (1) (kinematic viscosity of 8.5 mm²/s, vinyl value of 0.21 (mol/100 g)) and 16 g of a polymethylhydrosiloxane represented by formula (2) (kinematic viscosity of 121 mm²/s, H value of 0.85 mol/100 g), and the reaction mixture was mixed and stirred at 2,000 rpm using a homogenizing mixer. Subsequently, 38 g of water and 24 g of boron nitride (SP-3, manufactured by Denka Company Limited) were added to the reaction mixture, and stirring was continued at 8,000 rpm. Upon continued stirring, phase inversion occurred and thickening was observed. Thereafter, 240 g of dilution water was added to dilute the reaction mixture, thereby obtaining an O/W-type silicone oil emulsion.

The silicone oil emulsion was then transferred to a glass flask equipped with a stirring device having an anchor impeller, followed by adding 0.84 g of a toluene solution of a chloroplatinic acid-olefin complex (platinum content of 0.5%) with stirring at room temperature. After reacting for 12 hours, an aqueous dispersion liquid of the composite fine particle was obtained. The solid component was about 210%.

### Comparison Preparation Example 1

In a 0.5-L glass beaker, were placed 56 g of a methylvinylsiloxane represented by formula (1) (kinematic viscosity of 8.5 mm²/s, vinyl value of 0.21 (mol/100 g)) and 16 g of a polymethylhydrosiloxane represented by formula (2) (kinematic viscosity of 121 mm²/s, H value of 0.85 mol/100 g), and the reaction mixture was mixed and stirred at 2,000 rpm using a homogenizing mixer. Subsequently, 0.22 g of polyoxyethylene (9 mol added) lauryl ether and 38 g of water were then added to the reaction mixture, and stirring was continued at 8,000 rpm. Upon continued stirring, phase inversion occurred and thickening was observed. Thereafter, 240 g of dilution water was added to dilute the reaction mixture, thereby obtaining an O/W-type silicone oil emulsion.

The silicone oil emulsion was then transferred to a glass flask equipped with a stirring device having an anchor impeller, followed by adding a mixture of 0.84 g of a toluene solution of a chloroplatinic acid-olefin complex (platinum content of 0.5%) and 1.92 g of polyoxyethylene (9 mol added) lauryl ether with stirring at room temperature. After reacting for 12 hours, an aqueous dispersion liquid of fine particles was obtained. The solid component was about 21%.

### Examples 1 to 3 and Comparative Example 1

### Preparation of Silicone Rubber Composite Fine Particles

In a 500-ml glass flask were 200 g of water, were placed 182 g of the aqueous dispersion liquid of the composite obtained in Preparation Examples 1 to 3 or the aqueous dispersion liquid of the fine particle obtained in Comparison Preparation Example 1 (each with a solid component of about 21%), and 19.6 g of an aqueous solution of ammonia (concentration of 25% by weight), followed by setting the water temperature to 10 °C and stirring with an anchor impeller with a blade rotational speed of 150 rpm. The pH of the dispersion liquid at this time was 12.7. Subsequently, 18 g of methyltrimethoxysilane (KBM-13, manufactured by Shin-Etsu Chemical Co., Ltd.) was added dropwise to the dispersion liquid while maintaining the liquid temperature at 5 to 15 °C over 20 minutes, followed by stirring for 1 hour. The reaction mixture was then heated to 55 to 60 °C, followed by stirring for 1 hour. The reaction solution thus obtained was made into a cake-like product using a vacuum filter, followed by drying for 55 °C×16 h or more and jet milling to obtain the silicone rubber composite fine particles.

The blending ratios (parts by mass) of each component and the volume-based average particle diameters of the silicone rubber composite fine particles obtained in Examples 1 to 3 and Comparative Example 1 are shown in Table 1. The method for measuring the average particle diameter is as described above.

TABLE 1

| | | | | | | Comparative |
|---|---|---|---|---|---|---|
| | | | Example | | | Example |
| Parts by mass | | | 1 | 2 | 3 | 1 |
| (A) | (a1) | Methylvinylsiloxane | 43.9 | 49.1 | 41.2 | 51 |
| | (a2) | Methylhydrogenpolysiloxane | 13.8 | 15.4 | 12.9 | 16 |

| | | | | | |
|---|---|---|---|---|---|
| (B) | Boron nitride | 12.6 | 3.5 | 17.6 | |
| (C) | Methyltrimethoxysilane | 29.7 | 32 | 28.3 | 33 |

| | | | | |
|---|---|---|---|---|
| Particle size, μm | 5 | 0.6 | 2 | 3.9 |

### Examples 4 to 6 and Comparative Examples 2 to 4

### Preparation of Thermosetting Resin Composition

Thermosetting resin compositions were prepared by blending an epoxy resin, a curing agent, and the silicone rubber fine particles obtained in each of the above Examples in the compositions and amounts shown in the following Table. The resulting thermosetting resin compositions were cured according to the method described below. Each cured product thus obtained was subjected to a bending test and a dielectric loss tangent measurement. The results are shown in Table 2.

The epoxy resin and the curing agent used in the Examples and the Comparative Examples were as shown below.
Mixture of bisphenol A-type epoxy resin and bisphenol F-type epoxy resin:
   ZX-1059 (epoxy equivalent: 160-170, viscosity (25 °C) of 1,900 to 2,600 mPa·s, manufactured by Nippon Steel Chemical & Material Co., Ltd.)
Aromatic amine catalyst represented by the following formula: KAYAHARD A-A (manufactured by Nippon Kayaku Co., Ltd.)

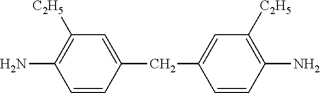 [SMILES: CCc1cc(Cc2ccc(N)c(CC)c2)ccc1N]

The measurement method and the measurement conditions were as follows.

### Bending Test

Each thermosetting resin composition was mixed for 10 minutes, followed by vacuum degassing at 60 °C, and then injected into a mold having a thickness of 4 mm. The mold was heated at 150 °C for 4 hours, then cooled, and the cured product was removed from the mold. The cured product thus obtained was cut to the dimensions described below using a diamond cutter, and a bending test was performed to measure the flexural modulus (MPa). The bending test was conducted using an Autograph (manufactured by Shimadzu Corporation) in accordance with Japanese Industrial Standard (JIS) K 7171. The test conditions were a support span length of 64 mm, a speed of 2 mm/min, and a sample thickness of 4 mm. The flexural modulus is preferably less than 2,700 MPa.

### Dielectric Loss Tangent

The dielectric constant and dielectric loss tangent at 60 GHz were measured by a free-space method using a network analyzer. The dielectric loss tangent is preferably less than 0.029.

TABLE 2

| | | Example | | | Comparative Example | | |
|---|---|---|---|---|---|---|---|
| Parts by mass | | 4 | 5 | 6 | 2 | 3 | 4 |
| Thermosetting | Epoxy resin | 72 | 72 | 72 | 72 | 72 | 72 |
| resin | | | | | | | |
| Curing agent | Aromatic | 28 | 28 | 28 | 28 | 28 | 28 |
| | amine-based catalyst | | | | | | |
| Fine particles | Example 1 | 8 | | | | | |
| | Example 2 | | 8 | | | | |
| | Example 3 | | | 8 | | | |
| | Comparative | | | | | | 8 |
| | Example 1 | | | | | | |
| | Boron nitride | | | | | 8 | |
| Property | Flexural modulus, MPa | 2157.12 | 2590.39 | — | 2775.39 | 3496.21 | 2316.74 |
| | Dielectric loss | — | 0.0261 | 0.0268 | 0.0295 | 0.0248 | 0.0282 |
| | tangent, 60 GHz | | | | | | |

As shown in Table 2, the silicone rubber composite fine particles of the present invention has the softness of silicone rubber and provides the cured product with a low dielectric loss tangent. By adding the silicone rubber composite fine particles containing boron nitride to the thermosetting resin composition, the flexural modulus ratio is lower and the cured product is softer than those of a cured product (Comparative Example 3) obtained by adding only boron nitride to the thermosetting resin composition.

The silicone rubber composite fine particles of the present invention provide a thermosetting resin composition that give a cured product having a lower flexural modulus, a lower dielectric constant, and a lower dielectric loss tangent as compared with conventional silicone rubber fine particles and provide a single-layer resin sheet, a laminated resin sheet, a prepreg, a metal-foil-clad laminate, a printed wiring board, an encapsulating material, a fiber-reinforced composite material, and an adhesive. The thermosetting resin composition is useful as an encapsulant for semiconductor elements and the like, and can be suitably used as an encapsulant by, for example, coating an object such as an electronic circuit board by a known coating method.

1. A silicone rubber composite fine particle having an average particle size of 0.1 to 100 μm, comprising
a composite containing (A) a silicone rubber particle and (B) at least one inorganic powder selected from the group consisting of silica, boron nitride, and aluminum nitride, and
(C) a condensate of an organoalkoxysilane.

2. The silicone rubber composite fine particle according to claim 1, comprising
0.1 to 80% by mass of (A) the silicone rubber particle,
0.1 to 80% by mass of (B) at least one inorganic powder selected from the group consisting of silica, boron nitride, and aluminum nitride, and
0.1 to 80% by mass of (C) the condensate of the organoalkoxysilane,
each based on 100% by mass of the silicone rubber composite fine particle.

3. The silicone rubber composite fine particle according to claim 1, wherein the silicone rubber of component (A) has a structure represented by the following formula (1):
—(R¹₂SiO)ₐ— (1)
wherein, in formula (1), R¹ is, independently of each other, a substituted or unsubstituted monovalent hydrocarbon group having 1 to 20 carbon atoms, and a is an integer of 5 to 5,000.

4. The silicone rubber composite fine particle according to claim 1, wherein the organoalkoxysilane (C) is at least one selected from the group consisting of a trialkoxysilane represented by the following general formula (2) and a tetraalkoxysilane represented by the following general formula (3):
R²Si(OR³)₃ (2)
Si(OR³)₄ (3)
wherein, in formula (2), R² is a monovalent hydrocarbon group having 1 to 20 carbon atoms, and in formulas (2) and (3), R³ is, independently of each other, an alkyl group having 1 to 6 carbon atoms.

5. The silicone rubber composite fine particle according to claim 1, wherein the silicone rubber composite fine particle consists of the composite of (A) the silicone rubber particle and (B) at least one inorganic powder selected from the group consisting of silica, boron nitride, and aluminum nitride, and (C) the condensate of the organoalkoxysilane.

6. A thermosetting resin composition comprising a thermosetting resin and the silicone rubber composite fine particle according to claim 1,
wherein an amount of the silicone rubber composite fine particle is 0.5 to 80 parts by mass, relative to 100 parts by mass of the thermosetting resin.

7. A cured product of the thermosetting resin composition according to claim 6.

8. A semiconductor element encapsulated with the cured product according to claim 7.

9. A method for preparing a silicone rubber composite fine particle, comprising steps of
mixing (A′) a curable organopolysiloxane composition; (B) at least one inorganic powder selected from the group consisting of silica, boron nitride, and aluminum nitride; water; and optionally a surfactant, and curing the curable organopolysiloxane composition to obtain an aqueous dispersion of a composite, and
subjecting (C) an organoalkoxysilane to a hydrolysis and condensation reaction in the aqueous dispersion of the composite obtained in the said step, to obtain the silicone rubber composite fine particle having an average particle size of 0.1 to 100 μm.

10. The method for preparing the silicone rubber composite fine particle according to claim 9, wherein an amount of component (B) is 0.1 to 80 parts by mass and an amount of component (C) is 0.1 to 80 parts by mass, relative to total 100 parts by mass of the organopolysiloxane contained in component (A′), the inorganic powder (B), and the organoalkoxysilane (C).

11. The method for preparing the silicone rubber composite fine particle according to claim 9, wherein the curable organopolysiloxane composition (A′) is a condensation-curable organopolysiloxane composition, a radical-curable organopolysiloxane composition, or an addition-curable organopolysiloxane composition.

12. The method for preparing the silicone rubber composite fine particle according to claim 9, wherein the organoalkoxysilane (C) is at least one selected from the group consisting of a trialkoxysilane represented by the following general formula (2) and a tetraalkoxysilane represented by the following general formula (3):
R²Si(OR³)₃ (2)
Si(OR³)₄ (3)
wherein, in formula (2), R² is a monovalent hydrocarbon group having 1 to 20 carbon atoms, and, in formulas (2) and (3), R³ is, independently of each other, an alkyl group having 1 to 6 carbon atoms.

13. A thermosetting resin composition comprising a thermosetting resin and the silicone rubber composite fine particle according to claim 2,
wherein an amount of the silicone rubber composite fine particle is 0.5 to 80 parts by mass, relative to 100 parts by mass of the thermosetting resin.

14. A cured product of the thermosetting resin composition according to claim 13.

15. A semiconductor element encapsulated with the cured product according to claim 14.

16. A thermosetting resin composition comprising a thermosetting resin and the silicone rubber composite fine particle according to claim 3,
wherein an amount of the silicone rubber composite fine particle is 0.5 to 80 parts by mass, relative to 100 parts by mass of the thermosetting resin.

17. A cured product of the thermosetting resin composition according to claim 16.

18. A semiconductor element encapsulated with the cured product according to claim 17.

19. A thermosetting resin composition comprising a thermosetting resin and the silicone rubber composite fine particle according to claim 4,
wherein an amount of the silicone rubber composite fine particle is 0.5 to 80 parts by mass, relative to 100 parts by mass of the thermosetting resin.

20. A thermosetting resin composition comprising a thermosetting resin and the silicone rubber composite fine particle according to claim 5,
wherein an amount of the silicone rubber composite fine particle is 0.5 to 80 parts by mass, relative to 100 parts by mass of the thermosetting resin.
